(19) United States
(12) Patent Application Publication
(10) Pub. No.: US 2026/0247544 A1
(43) Pub. Date: Aug. 20, 2026

(54) ELECTRONIC CIRCUIT BOARD, IMAGE FORMING APPARATUS, AND METHOD FOR MANUFACTURING ELECTRONIC CIRCUIT BOARD

(71) Applicant: CANON KABUSHIKI KAISHA, Tokyo (JP)

(72) Inventor: TAKAYUKI MIYAMOTO, Tokyo (JP)

(21) Appl. No.: 19/535,252

(22) Filed: Feb. 10, 2026

(30) Foreign Application Priority Data
Feb. 19, 2025 (JP) 2025-024876

(51) Int. Cl. H05K 3/341; B41M 1/12; B41M 1/26; G03G 15/00; H05K 1/02; H05K 1/11; H05K 1/181; H05K 3/3452

(52) U.S. Cl. CPC H05K 3/341; B41M 1/12; B41M 1/26; G03G 15/80; H05K 1/023; H05K 1/111; H05K 1/181; H05K 3/3452

(57) ABSTRACT

An electronic circuit board for an image forming apparatus includes a substrate having a first land and a second land, and at least one component mounted on the substrate by solder provided on the first land and solder provided on the second land. A per-unit-area solder amount of the solder provided on the first land differs from a per-unit-area solder amount of the solder provided on the second land.

### BACKGROUND

### Field of the Technology

The present disclosure relates to an electronic circuit board on which a component is mounted by solder, an image forming apparatus including an electronic circuit board, and a method for manufacturing an electronic circuit board on which a component is mounted by using solder.

### Description of the Related Art

Components are mounted on an electronic circuit board used in an image forming apparatus such as a copier or a printer using solder. Japanese Patent Application Laid-Open No. 2014-179423 A discloses a shield component mounted on an electronic circuit board by soldering.

However, in Japanese Patent Application Laid-Open No. 2014-179423, the solder amount used for soldering a component is not examined. Depending on the solder amount used for soldering, there is a possibility that the electronic circuit board or the mounted component may not be able to realize a desired function.

### SUMMARY

In view of the above-described problems, the present disclosure is directed to enable an electronic circuit board and a functional unit having components soldered to the electronic circuit board to function appropriately.

According to a first aspect of the present disclosure, an electronic circuit board for an image forming apparatus includes a substrate having a first land and a second land, and at least one component mounted on the substrate by solder provided on the first land and solder provided on the second land. A per-unit-area solder amount of the solder provided on the first land differs from a per-unit-area solder amount of the solder provided on the second land.

According to a second aspect of the present disclosure, an image forming apparatus includes a functional unit configured to perform at least a part of image forming functions. The functional unit includes the electronic circuit board.

According to a third aspect of the present disclosure, a method for manufacturing an electronic circuit board includes preparing a substrate having a first land and a second land, preparing a mask having a first opening and a second opening, overlaying the mask on the substrate such that the first land is exposed through the first opening and the second land is exposed through the second opening, disposing a solder material on the mask overlaying the substrate, removing the mask from the substrate after disposing the solder material on the mask overlaying the substrate, placing at least one component on the substrate after removing the mask from the substrate, and reflowing the solder material remaining on the substrate after placing the at least one component on the substrate. A ratio of a size of the first opening to an area of the first land exposed through the first opening differs from a ratio of a size of the second opening to an area of the second land exposed through the second opening.

Features of the present disclosure will become apparent from the following description of embodiments with reference to the attached drawings. The following description of embodiments is described by way of example.

### BRIEF DESCRIPTION OF THE DRAWINGS

FIG. 1 is a perspective view illustrating an image forming apparatus.

FIG. 2 is a schematic view illustrating an image forming apparatus.

FIG. 3 is a perspective view illustrating the image forming apparatus as viewed from the rear.

FIG. 4 is a top view illustrating the electronic circuit board of the first embodiment.

FIG. 5 is a perspective view illustrating a shield component according to the first embodiment.

FIG. 6 is a cross-sectional view illustrating a cross section taken along line A-A in FIG. 4.

FIG. 7A is an enlarged view illustrating an edge portion of a shield component.

FIG. 7B is an enlarged view illustrating a land.

FIG. 7C is a cross-sectional view taken along line B-B in FIG. 7B.

FIG. 7D is a cross-sectional view taken along line C-C in FIG. 7B.

FIG. 7E is a cross-sectional view taken along line D-D in FIG. 7B.

FIG. 8A is a view for explaining an electronic circuit board of a second embodiment, and is a schematic view illustrating a part of an electronic component.

FIG. 8B is a view for explaining an electronic circuit board of a second embodiment, and is a schematic view illustrating a solder amount per unit area.

FIG. 9 is a cross-sectional view illustrating an electronic circuit board according to a third embodiment.

FIG. 10 is a top view illustrating an electronic circuit board of a fourth embodiment.

FIG. 11 is a perspective view illustrating a shield component in a fourth embodiment.

FIG. 12 is a top view illustrating an example of an electronic circuit board having a land.

FIG. 13A is a view for explaining reflow soldering, and is a view of a step of overlapping a mask on an electronic circuit board and applying a solder paste.

FIG. 13B is a view for explaining reflow soldering, and is a view of a step of removing a mask from an electronic circuit board.

FIG. 13C is a view for explaining reflow soldering, and is a view of a step of placing an electronic component and a shield component on an electronic circuit board.

FIG. 13D is a view for explaining reflow soldering, and is a view of a reflow step.

FIG. 14 is a schematic view illustrating a shape of a mask.

FIG. 15A is an enlarged view for explaining the method for controlling the solder amount by reflow soldering of the present embodiment, and is a view of a step of overlapping a mask on an electronic circuit board and applying a solder paste.

FIG. 15B is an enlarged view for explaining the method for controlling the solder amount by reflow soldering of the present embodiment, and is a view of a step of removing a mask from an electronic circuit board.

FIG. 15C is an enlarged view for explaining the method for controlling the solder amount by reflow soldering of the present embodiment, and is a view of a reflow step.

### DESCRIPTION OF THE EMBODIMENTS

### First Embodiment

### Image Forming Apparatus

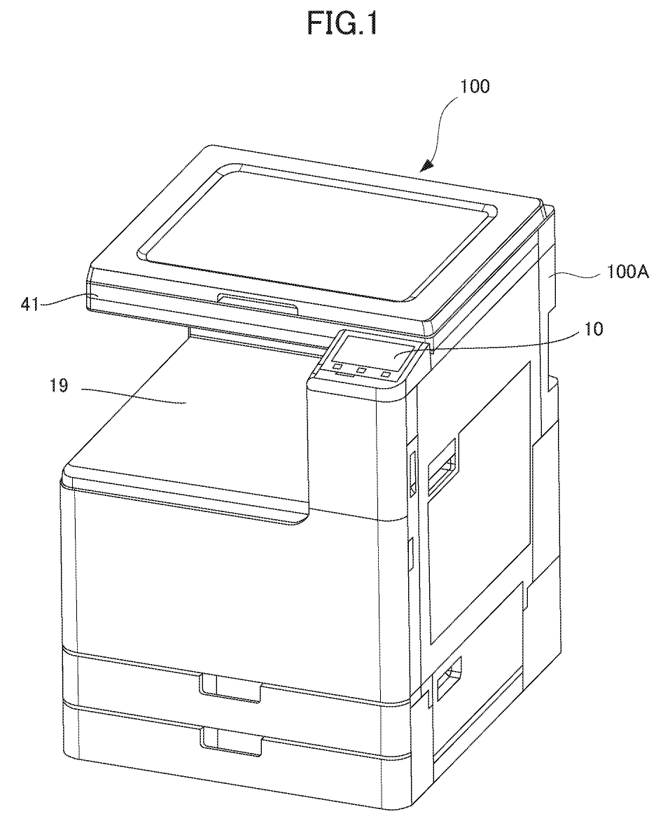

Hereinafter, the present embodiment will be described. An electronic circuit board to which the present technology described later is applied can be used for various devices. For example, an electronic circuit board to which the present technology is applied is used in an image forming apparatus that forms an image on a recording material. Therefore, a representative embodiment of the present technology will be described with an image forming apparatus as an example. First, an image forming apparatus will be described with reference to FIGS. 1 to 3. FIGS. 1 to 3 illustrate the internal discharge type image forming apparatus 100 as an example.

An image forming apparatus 100 illustrated in FIG. 1 includes an apparatus body 100A and a document reading apparatus 41 that reads image information of a document, and a sheet discharge tray 19 on which a recording material S discharged from the apparatus body 100A is stacked is provided between the apparatus body 100A and the document reading apparatus 41. The image forming apparatus 100 forms, on a recording material, a toner image corresponding to image data sent from an external device (not illustrated) such as the document reading apparatus 41 or a personal computer (PC).

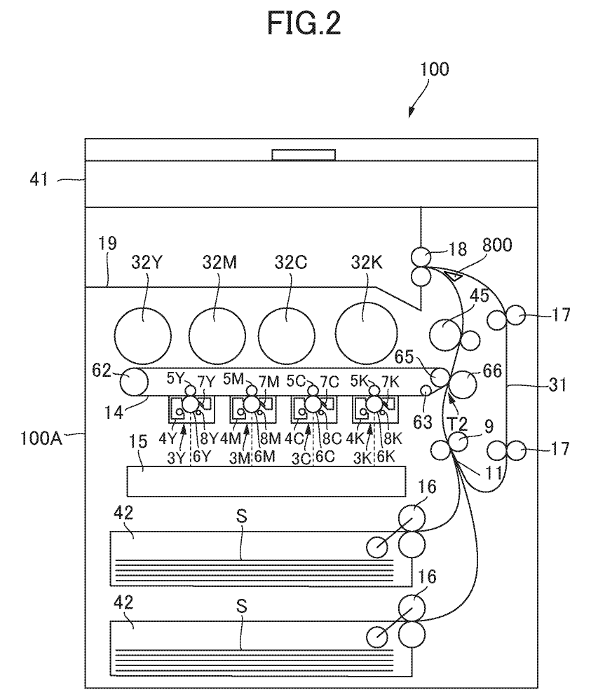

A conveyance process of the recording material of the image forming apparatus 100 will be described. As illustrated in FIG. 2, the recording material S is stored in a form of being stacked in the cassette 42, and is supplied to the conveyance path 11 one by one in accordance with the image forming timing by the supply roller 16. In addition, recording materials S stacked on a manual sheet feeding tray (not illustrated) may be fed to the conveyance path 11 one by one. When the recording material S is conveyed to the registration roller 9 disposed in the middle of the conveyance path 11, skew correction and timing correction of the recording material S are performed by the registration roller 9, and then the recording material S is sent to the secondary transfer portion T2. The secondary transfer portion T2 is a transfer nip portion formed by the secondary transfer inner roller 65 and the secondary transfer outer roller 66 facing each other. In the secondary transfer portion T2, a secondary transfer voltage is applied to the secondary transfer inner roller 65, whereby the toner image is secondarily transferred from the intermediate transfer belt 14 to the recording material S.

An image formation process of an image sent to the secondary transfer portion T2 at the same timing as the conveyance process of the recording material S to the secondary transfer portion T2 will be described. First, the image forming units 3Y, 3M, 3C, and 3K will be described. However, the image forming units 3Y to 3K are configured substantially the same except that the colors of toners used in the developing devices 4Y, 4M, 4C, and 4K are yellow, magenta, cyan, and black, respectively. Therefore, hereinafter, the yellow image forming unit 3Y will be described as a representative example, and description of the other image forming units 3M, 3C, and 3K will be omitted.

The image forming unit 3Y includes a photosensitive drum 6Y, a charger 8Y, a developing device 4Y, and a drum cleaner 7Y. The surface of the photosensitive drum 6Y is uniformly charged in advance by the charger 8Y along with the application of the charging voltage, and then an electrostatic latent image is formed by the exposure device 15 driven on the basis of a signal of image information. The electrostatic latent image formed on the photosensitive drum 6Y is developed into a toner image by the developing device 4Y using a developer with application of a developing voltage. Thereafter, a predetermined pressurizing force and a primary transfer voltage are applied by the primary transfer roller 5Y disposed opposite to the image forming unit 3Y with the intermediate transfer belt 14 interposed therebetween, and the toner image formed on the photosensitive drum 6Y is primarily transferred onto the intermediate transfer belt 14. The transfer residual toner slightly remaining on the photosensitive drum 6Y after the primary transfer is removed by the drum cleaner 7Y to prepare for the next image forming process again.

Above the intermediate transfer belt 14, toner bottles 32Y to 32K containing replenishment toners to be replenished to the developing devices 4Y to 4K are detachably provided to a toner replenishing mechanism (not illustrated). From the toner bottles 32Y to 32K, an appropriate amount of toner is supplied to the corresponding developing devices 4Y to 4K at appropriate times by a toner replenishing mechanism.

The intermediate transfer belt 14 is stretched by a secondary transfer inner roller 65 and a plurality of stretching rollers 62 and 63, and is driven to move counterclockwise in FIG. 2. The image formation process of each color processed by the image forming units 3Y to 3K is performed at the timing of sequentially superimposing the toner images of the colors upstream in the moving direction primarily transferred onto the intermediate transfer belt 14. As a result, a full-color toner image is finally formed on the intermediate transfer belt 14 and conveyed to the secondary transfer portion T2. The transfer residual toner after passing through the secondary transfer portion T2 is removed from the intermediate transfer belt 14 by a secondary transfer cleaner (not illustrated).

By the conveying process and the image forming process described above, the timings of the recording material S and the full-color toner image coincide with each other in the secondary transfer portion T2, and the toner image is secondarily transferred from the intermediate transfer belt 14 to the recording material S. Thereafter, the recording material S is conveyed to the fixing device 45, and is heated and pressurized by the fixing device 45, whereby the toner image is fixed on the recording material S. In the case of single-sided printing, the recording material S on which the toner image has been fixed is discharged to the sheet discharge tray 19 by the discharge roller 18 rotating in the forward rotation direction. On the other hand, in the case of double-sided printing, the recording material S is conveyed until the rear end of the recording material S passes through the switching member 800 by the discharge roller 18 rotating in the forward rotation direction, and then the front and rear ends are switched by the discharge roller 18 whose rotation has been switched in the reverse rotation direction and conveyed to the double-sided conveyance path 31. Thereafter, the recording material S is again sent to the conveyance path 11 by the re-conveying roller 17. The subsequent conveyance and the image forming process of the second surface are similar to those in the above-described case, and thus the description thereof is omitted.

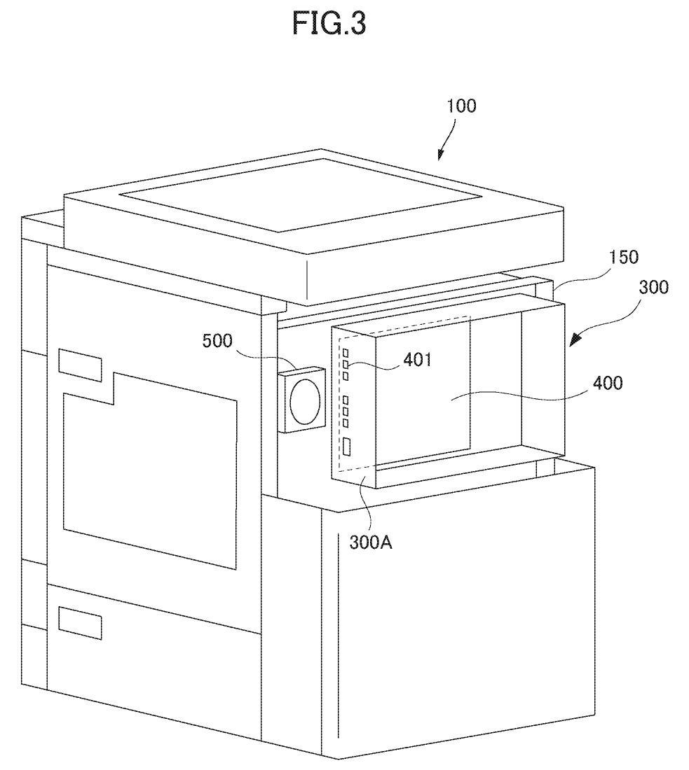

Note that the recording material S subjected to the fixing processing needs to be cooled in order to avoid image defects due to fusion of toner and adhesion between sheets. Therefore, a cooling fan 500 (see FIG. 3) is disposed above the fixing device 45 and on the back surface side of the main body, and the recording material S passing through the conveyance path 11 can be cooled by performing exhaust heat of the conveyance path 11 by the air flow exhausting to the rear side.

### Control board

FIG. 3 is a perspective view illustrating the image forming apparatus 100 as viewed from the rear. However, FIG. 3 illustrates a state in which a part of the exterior cover of the image forming apparatus 100 is removed. As illustrated in FIG. 3, a controller box 300 is provided on the rear plate 150 side. FIG. 3 illustrates the controller box 300 in a state where the electric cover is removed. Therefore, the control board 400 built in the controller box 300 is in a visible state. Since the controller box 300 also serves as a fixed seat surface of the exterior cover, the controller box 300 is fixed at a position separated from the rear plate 150 by a predetermined distance in accordance with the position of the exterior cover. The cooling fan 500 that exhausts heat from the conveyance path 11 is fixed to the rear plate 150 so as not to overlap with the controller box 300.

The control board 400 is an electronic circuit board that controls the image forming apparatus 100 such as the above-described image forming process. Even when the user operates the image forming apparatus 100 via the network, control is performed via the control board 400. A plurality of communication connectors including a LAN (Local Area Network) connector for connection to a network in an installation environment is mounted on the control board 400. A plurality of openings 401 are provided on the side surface 300A of the controller box 300 so that the communication connector of the control board 400 can be accessed. Note that the communication connector assumed to be used by the user can be accessed in a state where the external cover is attached.

Meanwhile, one or a plurality of functional units is mounted on the image forming apparatus 100 in order to execute various functions. In recent years, with the development and spread of mobile terminals (For example, a notebook PC or a smartphone), the mobile terminals and the image forming apparatus 100 can communicate with each other via a wireless LAN. As a functional unit to which the wireless LAN function is added, a wireless communication unit (not illustrated) is provided in the image forming apparatus 100. In a case where the wireless communication unit is provided, it is possible to cause the image forming apparatus 100 to form an image based on the image data stored in the mobile terminal under the control of the user from the mobile terminal.

However, the electromagnetic waves transmitted and received by the wireless communication unit may be noise for electronic components mounted on other electronic circuit boards provided in the image forming apparatus 100. In addition, even if the wireless communication unit is not provided, an electronic component mounted on an electronic circuit board included in a certain functional unit may be a noise source. Furthermore, an electromagnetic wave outside the image forming apparatus 100 may become noise for an electronic component mounted on an electronic circuit board provided in the image forming apparatus 100.

Therefore, in an electronic circuit substrate (also simply referred to as a substrate) provided in the image forming apparatus 100 of the present embodiment, a shield component that covers an electronic component is mounted on the substrate in order to suppress the influence of noise on the electronic component mounted on the substrate. The shield component is formed of a conductive material such as metal. The shield component may be disposed to protect the electronic component from noise as a shielding object. Alternatively, the shield component may be disposed so as to cover an electronic component that can be a noise source by emitting an electromagnetic wave.

However, when the shield component is mounted in a state where a gap is generated between the substrate and the shield component, noise generated in the electronic component in the shield component may leak from the gap to the outside of the shield component. Alternatively, external noise may enter the shield component through the gap, and the noise may affect the electronic component in the shield component. Therefore, it is desirable not to generate a gap between the substrate and the shield component or to reduce the gap.

The shield component is typically manufactured by molding a sheet metal using a mold and then performing processing such as bending. In a case where the shield component is mounted on the substrate by soldering, in order to prevent generation of a gap between the substrate and the shield component, it is sufficient that lower end portions (referred to as edge portions) of a plurality of side surface portions surrounding the electronic component in the shield component are all brought into contact with the substrate without a gap. However, the shield component manufactured as described above is likely to cause a processing error for each individual, and it may be difficult to bring all of the edge portions of the shield component into contact with the substrate. As a result, of the plurality of edge portions of the shield component, an edge portion in contact with the substrate and an edge portion in which a gap is generated between the edge portion and the substrate may be generated. In addition, in the case of the edge portion in which the gap is partially generated, a portion in which the gap is relatively larger and a portion in which the gap is relatively smaller may be generated.

In view of the above points, in the present embodiment, the solder amount is controlled when the shield component is mounted on the substrate, and the gap between the shield component and the substrate can be reduced or filled. The "control of the solder amount" mentioned here is to change the solder amount per unit area according to the position of the substrate on which the shield component is mounted. Note that the above-described reduction or elimination of the gap between the shield component and the substrate is one of the purposes of controlling the solder amount, but in other embodiments described later, the solder amount can be controlled for different purposes. In the present embodiment, the shield component and the electronic component are examples of a component or a first component, and correspond to at least one component.

### Electronic circuit board

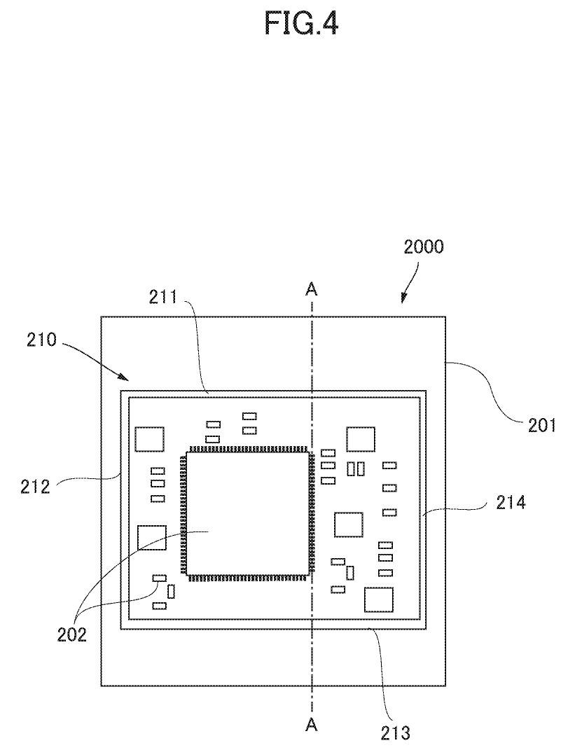

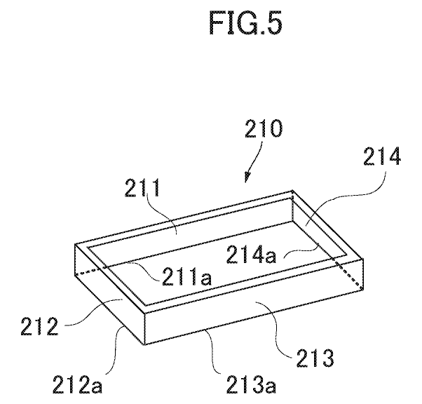

An outline of the electronic circuit board of the present embodiment will be described with reference to FIGS. 4 and 5. FIG. 4 is a top view illustrating the electronic circuit board of the present embodiment. As illustrated in FIG. 4, the electronic circuit board 201 is included in a functional unit 2000 that implements some or all of the functions of the image forming apparatus 100. For example, the electronic circuit board 201 of the present embodiment is used as a functional unit such as the control board 400 and the wireless communication unit described above. Alternatively, although not illustrated, the electronic circuit board 201 of the present embodiment may also be used as a functional unit such as a drive control unit that controls a drive motor that drives various rotary members and various rollers in the image forming units 3Y to 3K.

A wiring pattern (not illustrated) is formed on the electronic circuit board 201 included in the functional unit 2000. The wiring pattern is a conductive pattern printed with a conductive material in order to electrically connect electronic components mounted on the electronic circuit board 201. On the electronic circuit board 201, an electronic component 202 and a shield component 210 are mounted according to a wiring pattern. The electronic component 202 and the shield component 210 are examples of components mounted on the electronic circuit board 201. The electronic component 202 and the shield component 210 are mounted on the electronic circuit board 201 by soldering. In the electronic circuit board 201, a pattern made of a conductive material is exposed on the surface at a portion where the electronic component 202 and the shield component 210 are mounted. The pattern made of the conductive material exposed on the surface of the electronic circuit board 201 is referred to as a "land" for the sake of convenience. The land is formed on the electronic circuit board 201 at a mounting position where the electronic component 202 and the shield component 210 are mounted. The land may be formed integrally with the wiring pattern as part of a conductive pattern.

Note that the electronic circuit board 201 in a state where no component is mounted can be referred to as a printed wiring board (PWB). The electronic circuit board 201 on which the components are mounted can be referred to as a printed circuit board (PCB).

The electronic component 202 is a passive element such as a resistor, a capacitor, or a coil, a functional integrated circuit (IC) chip having a specific function, or the like. A connector for connecting the functional unit 2000 to an external device or the like is also an example of the electronic component 202. These electronic components 202 have conductive terminals. Terminals of the electronic component 202 are electrically and physically bonded to lands of the electronic circuit board 201 by solder. The functional unit 2000 can realize a desired function by bonding the electronic component 202 to the electronic circuit board 201.

The shield component 210 is made of a conductive material such as metal. The shield component 210 is physically bonded to the land of the electronic circuit board 201 by solder. By bonding the shield component 210 to the electronic circuit board 201, the shielding function of the electromagnetic wave by the shield component 210 and the ability to suppress the influence of noise are improved. As a result, the functional unit 2000 easily implements the desired function.

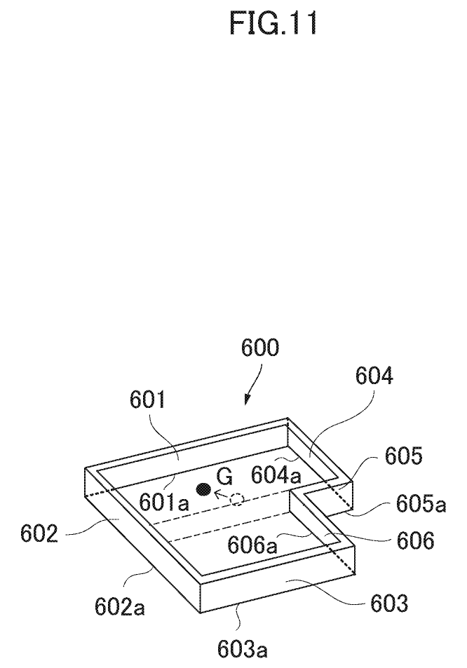

FIG. 5 is a perspective view illustrating the shield component 210. As illustrated in FIG. 5, the shield component 210 is formed in a rectangular shape having four side surface portions 211, 212, 213, and 214. An upper end portion of the side surface portion 211~214 is bent toward the inside of the shield component 210. The shield component 210 is manufactured by cutting out one sheet metal with a mold and bending the sheet metal cut out so as to form the four side surface portions 211~214 illustrated in FIG. 5. Alternatively, the shield component 210 is manufactured by welding the four sheet metal members to form the four side surface portions 211~214 illustrated in FIG. 5. By such a manufacturing method, the shield component 210 is formed such that the four side surface portions 211, 212, 213, and 214 surround an object to be shielded such as the electronic component 202. Note that the shield component 210 is not limited to be formed in a rectangular shape, and may be formed in various shapes according to the arrangement of the shielded object (see FIG. 11 described later).

Note that the top surface of the shield component 210 illustrated in FIG. 5 is opened, but the present disclosure is not limited thereto, and as a modification, the shield component 210 may have a top plate that is not opened to the top surface. In the case of the shield component 210 in which the top surface is opened, there is an advantage that the heat radiation efficiency of the object to be shielded (for example, the electronic component 202) can be improved, and in the case of the shield component in which the top plate is provided on the top surface, there is an advantage that the effect of suppressing the influence of noise can be improved.

### Soldering

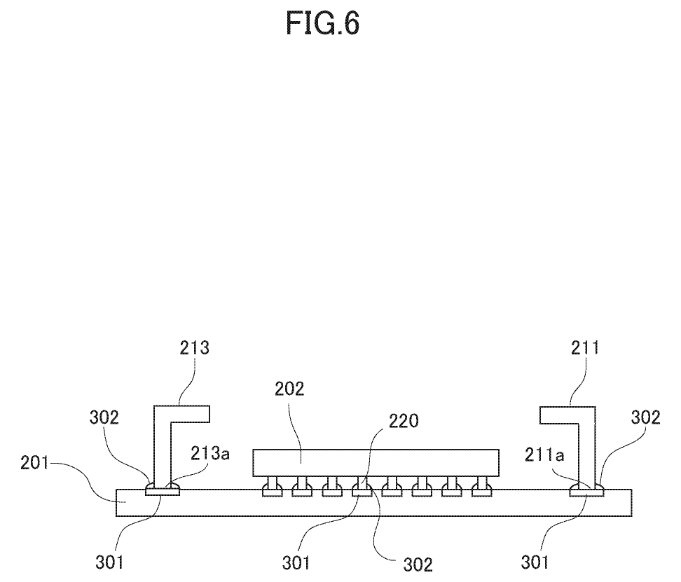

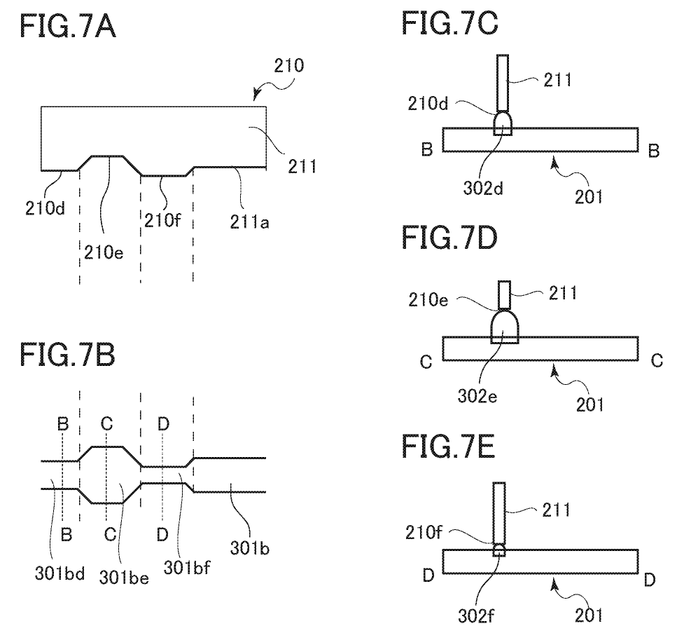

Next, soldering for mounting the electronic component 202 and the shield component 210 on the electronic circuit board 201 will be described with reference to FIGS. 6 to 7E while referring to FIG. 5. FIG. 6 is a cross-sectional view illustrating a cross section taken along line A-A of FIG. 4. As illustrated in FIG. 6, in the shield component 210, respective edge portions 211a and 213a facing the electronic circuit board 201 in the side surface portions 211 and 213 are soldered to the electronic circuit board 201. In addition, although not illustrated here, in the shield component 210, the edge portions 212a and 214a facing the electronic circuit board 201 in the side surface portions 212 and 214 are soldered to the electronic circuit board 201. On the other hand, in the electronic component 202, the plurality of terminals 220 are soldered to the electronic circuit board 201.

The electronic circuit board 201 is provided with a land 301. As described above, the land 301 is a portion where the conductive material is exposed on the surface of the electronic circuit board 201. The solder 302 is arranged on the land 301, and the electronic component 202 and the shield component 210 are arranged from above the arranged solder 302. The bonding by the solder 302 is performed by reflow soldering described later.

However, the shapes of the electronic component 202 and the shield component 210 may vary. The variation in the shape of the shield component 210 is caused by a manufacturing error or an external environment such as deformation due to temperature. As variation in the shape of the shield component 210, for example, unevenness may occur in the edge portions 211a to 214a (see FIG. 5) of the shield component 210. FIG. 7A illustrates a case where the edge portion 211a of the side surface portion 211 of the shield component 210 has irregularities as an example.

As illustrated in FIG. 7A, the edge 210e of the edge portion 211a is a recess with respect to the edge 210d. The edge 210f of the edge portion 211a is a protrusion with respect to both the edges 210d and 210e. When the shield component 210 is placed on the electronic circuit board 201, if there is a recess such as the edge 210e, a gap is generated between the shield component 210 (specifically, the edge 210e) and the electronic circuit board 201. Alternatively, when there is a protrusion such as the edge 210f, a relatively smaller gap is generated in the edge 210d, and a relatively larger gap is generated in the edge 210e.

As one method for soldering, a uniform solder amount material can be placed on the land to solder the shield component 210 to the electronic circuit board 201. However, when the shield component 210 in which the unevenness is generated is soldered, a gap may be generated between the shield component 210 and the electronic circuit board 201 at the edge 210e which is the concave portion. As described above, when the gap is generated, noise generated in the electronic component 202 in the shield component 210 easily leaks from the gap to the outside of the shield component 210. Alternatively, external noise enters the shield component 210 through the gap, and the noise may affect the electronic component 202 in the shield component 210. That is, the function of suppressing noise by the shield component 210 cannot be sufficiently obtained. On the other hand, there is a possibility that the solder protrudes from the land in the vicinity of the edge 210f serving as the convex portion. The solder protruding from the land may cause an unintended electrical short on the electronic circuit board 201. Therefore, when a uniform solder amount material is disposed on the land, there is a possibility that the functional unit 2000 having the electronic circuit board 201 to which the shield component 210 is soldered cannot execute the desired function.

Therefore, in the present embodiment, the solder amount per unit area varies depending on the position of the electronic circuit board 201 on which the shield component 210 is mounted. This point will be described below. FIG. 7B is an enlarged view illustrating a land, FIG. 7C is a cross-sectional view taken along line B-B in FIG. 7B, FIG. 7D is a cross-sectional view taken along line C-C in FIG. 7B, and FIG. 7E is a cross-sectional view taken along line D-D in FIG. 7B.

As illustrated in FIG. 7B, the width of the land 301b on the electronic circuit board 201 varies depending on the position of the electronic circuit board 201 on which the shield component 210 is mounted. For example, when the width of the land 301bd to which the edge 210d facing the electronic circuit board 201 is soldered among the edge portion 211a of the side surface portion 211 is set as a reference, the width of the land 301be to which the edge 210e facing the electronic circuit board 201 is soldered is long, and the width of the land 301bf to which the edge 210f facing the electronic circuit board 201 is soldered is short. The width of the land 301be is longer than the width of the land 301bf.

As illustrated in FIGS. 7C to 7E, based on the amount D per unit area of the solder 302d disposed on the land 301bd (second land) bonding the edge 210d (second portion, second edge), the amount E per unit area of the solder 302e disposed on the land 301be (first land) bonding the edge 210e (first portion, first edge) is greater. Conversely, the amount F per unit area of the solder 302f disposed on the land 301bf bonding the edge 210f is smaller than the amount D per unit area of the solder 302d disposed on the land 301bd bonding the edge 210d. The height of each solder varies depending on the solder amount disposed on each land. For example, the height of the solder 302e disposed on the land 301be is higher than the height of the solder 302d disposed on the land 301bd. The solder amount per unit area is obtained by dividing the mass of the solder in each land by the area of the land.

In the present embodiment, the unevenness of the edge of the shield component 210 is measured for each individual. Then, the solder amount per unit area is changed according to the unevenness of the edge portion 211a of the shield component 210. The solder amount per unit area may vary continuously. Alternatively, the unevenness of the edge portion 211a of the shield component 210 may be divided into a plurality of stages, and the solder amount per unit area may be set according to the number of stages.

Since the amount E per unit area of the solder 302e disposed on the land 301be bonding the edge 210e is relatively greater, the gap near the edge 210e becomes smaller. Alternatively, no gap is generated in the vicinity of the edge 210e. Therefore, even if the recess exists at the edge of the shield component 210, it is possible to suppress deterioration of the shielding function of the shield component 210. On the other hand, since the amount E per unit area of the solder 302e disposed on the land 301bf bonding the edge 210f is relatively smaller, the possibility that the solder unintentionally protrudes near the edge 210f is low. Therefore, the possibility that an unintended electrical short circuit occurs on the electronic circuit board 201 can be reduced.

As described above, in the present embodiment, the solder amount per unit area varies depending on the position of the electronic circuit board 201 on which the shield component 210 is mounted. As a result, even when there is a variation in the shape of the shield component 210, it is possible to reduce the gap between the shield component 210 and the electronic circuit board 201 or eliminate the gap between the shield component 210 and the electronic circuit board 201. That is, the shield component 210 is appropriately mounted on the electronic circuit board 201 by soldering. Therefore, the functional unit 2000 having the electronic circuit board 201 to which the shield component 210 is soldered can execute a desired function.

### Second Embodiment

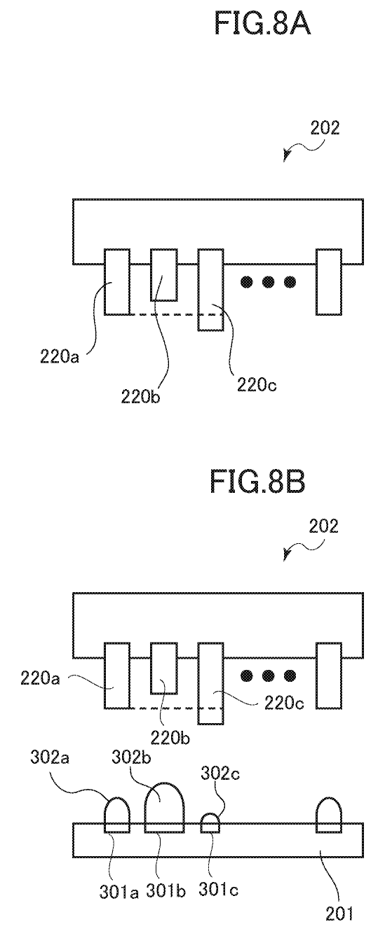

Next, a second embodiment will be described with reference to FIGS. 8A and 8B. The configuration of the second embodiment is the same as the configuration of the first embodiment described above except for the parts described below. Specifically, the configurations illustrated in FIGS. 4 to 6 and the description thereof are also applied to the second embodiment. Therefore, repeated description of a functional unit having an electronic circuit board is omitted.

As described above, the shapes of the electronic component 202 and the shield component 210 may vary due to a manufacturing error or due to an external environment such as deformation due to temperature. As a variation in the shape of the electronic component 202, the lengths of the plurality of terminals 220a, 220b, and 220c may be different as illustrated in FIG. 8A. In the example illustrated in FIG. 8A, when the length (second length) of the terminal 220a (second terminal) is set as a reference, the terminal 220b (first terminal) has a shorter length (first length) than the terminal 220a, and the terminal 220c has a longer length than the terminal 220a.

Hitherto, regardless of whether the lengths of the plurality of terminals are the same or not, a uniform solder amount material is disposed on all the lands to which the terminals 220a, 220b, and 220c are bonded, and the electronic component 202 is soldered to the electronic circuit board 201. However, when the electronic component 202 in which the length of the terminal is long or short is soldered, the relatively shorter terminal 220b may not be appropriately bonded to the electronic circuit board 201. In addition, for the relatively longer terminal 220c, the solder may protrude from the land. The solder protruding from the land may cause an unintended electrical short on the electronic circuit board 201. Therefore, in the conventional case, there is a possibility that an operation defective functional unit 2000 that cannot execute an intended function including not operating may be generated in the functional unit 2000 having the electronic circuit board 201 to which the electronic component 202 is soldered.

Therefore, in the present embodiment, the solder amount per unit area is varied according to the position of the electronic circuit board 201 on which the electronic component 202 is mounted. For example, as illustrated in FIG. 8B, when an amount A per unit area of the solder 302a disposed on the land 301a (second land) bonding the terminal 220a is used as a reference, an amount B per unit area of the solder 302b disposed on the land 301b (first land) bonding the terminal 220b is greater. Conversely, the amount C per unit area of the solder 302c disposed on the land 301c bonding the terminal 220c is smaller than the amount A per unit area of the solder 302a disposed on the land 301a bonding the terminal 220a. The amount of the solder per unit area is obtained by dividing the mass of the solder in the range of the land to which each terminal is bonded by the area of the land.

In the present embodiment, the length of the terminal 220 of the electronic component 202 is measured for each individual. Then, the solder amount per unit area is changed according to the length of the terminal 220. The solder amount per unit area may vary continuously. Alternatively, the length of the terminal 220 may be divided into a plurality of stages, and the solder amount per unit area may be set according to the number of stages.

Since the amount B per unit area of the solder 302b disposed on the land 301b to which the terminal 220b is bonded is relatively greater, the relatively shorter terminal 220b is appropriately bonded to the electronic circuit board 201. On the other hand, since the amount C per unit area of the solder 302c disposed on the land 301c to which the terminal 220c is bonded is relatively smaller, the possibility that the solder unintentionally protrudes near the terminal 220c is low. Therefore, the possibility that an unintended electrical short circuit occurs on the electronic circuit board 201 can be reduced.

As described above, in the present embodiment, the solder amount per unit area varies depending on the position of the electronic circuit board 201 on which the electronic component 202 is mounted. As a result, even when the shape of the electronic component 202 varies, the electronic component 202 is appropriately mounted on the electronic circuit board 201 by soldering. Therefore, the functional unit 2000 having the electronic circuit board 201 to which the electronic component 202 is soldered can execute a desired function. In the second embodiment, the bonding using the solder between the electronic component 202 and the electronic circuit board 201 has been described, but the bonding using the solder between the shield component 210 and the electronic circuit board 201 described above may also be used in combination in the second embodiment.

### Third Embodiment

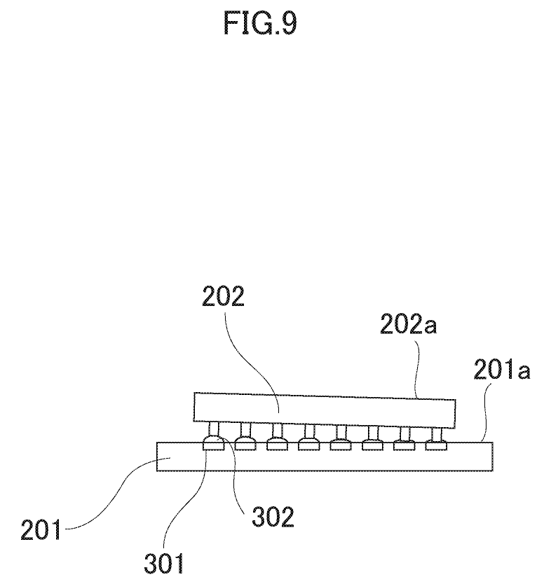

Next, a third embodiment will be described with reference to FIG. 9. In the first and second embodiments described above, the solder amount is controlled for the purpose of compensating for variations in the shape of the shield component 210 or the electronic component 202. On the other hand, in the third embodiment, the solder amount is controlled for the purpose of actively changing the characteristics of the component. The configuration of the third embodiment is the same as the configuration of the first embodiment described above except for the parts described below. Specifically, the configurations illustrated in FIGS. 4 to 6 and the description thereof are also applied to the third embodiment. Therefore, repeated description of a functional unit having an electronic circuit board is omitted.

As illustrated in FIG. 9, the electronic component 202 is mounted to be inclined with respect to the electronic circuit board 201. In other words, the top surface 202a of the electronic component 202 is not parallel to the mounting surface 201a of the electronic circuit board 201 on which the component is mounted. As described above, the configuration in which the components are mounted on the electronic circuit board 201 in an inclined manner is adopted for several purposes. For example, in a case where the electronic component 202 has an antenna that transmits and receives electromagnetic waves, there is a purpose of adjusting the directivity of the antenna. Alternatively, when the electronic component 202 has a reflecting surface that reflects light, there is a purpose of emitting the reflected light in a specific direction. Such an electronic component 202 may not have an electrical function.

In the present embodiment, the solder amount per unit area is varied according to the position of the electronic circuit board 201 on which the electronic component 202 is mounted so that the electronic component 202 can be mounted on the electronic circuit board 201 in an inclined manner. As illustrated in FIG. 9, a plurality of lands 301 are formed side by side on the electronic circuit board 201. In FIG. 9, the amount of the solder 302 per unit area of the land 301 formed at the left end is the greatest. The amount of the solder 302 per unit area decreases from the left to the right land 301. In the left land 301 (first land) where the solder amount per unit area is relatively greater, the electronic component 202 is mounted at a high position because the height of the solder is higher. Conversely, in the right land 301 (second land) where the solder amount per unit area is relatively smaller, the electronic component 202 is mounted at a low position because the height of the solder is low. As a result, the electronic component 202 is mounted on the electronic circuit board 201 in an inclined state.

As described above, the solder amount per unit area varies depending on the position of the electronic circuit board 201 on which the electronic component 202 is mounted. As a result, the electronic component 202 is appropriately mounted on the electronic circuit board 201. As a result, the functional unit 2000 can execute a desired function according to the purpose. Note that one or both of the bonding between the shield component 210 and the electronic circuit board 201 using solder and the bonding between the electronic component 202 and the electronic circuit board 201 using solder described above may also be used in combination in the third embodiment.

### Fourth Embodiment

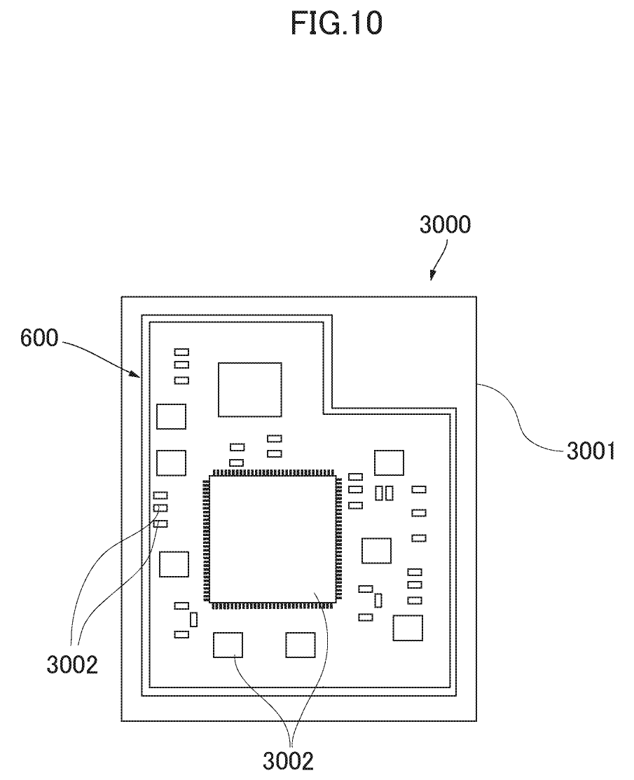

Next, a fourth embodiment will be described with reference to FIGS. 10 to 15C. The configuration of the fourth embodiment is the same as the configuration of the first embodiment described above except for the parts described below. Specifically, the configurations illustrated in FIGS. 4 to 6 and the description thereof are also applied to the fourth embodiment. Therefore, repeated description of a functional unit having an electronic circuit board is omitted.

The main difference between the fourth embodiment and the first embodiment described above is that the shape of the shield component 600 is different from the shape of the shield component 210 of the first embodiment. Hereinafter, main differences and accompanying differences will be described in detail.

### Shape of Shield Component

FIG. 10 is a top view illustrating the electronic circuit board of the present embodiment. As illustrated in FIG. 10, the functional unit 3000 has an electronic circuit board 3001. A wiring pattern (not illustrated) for electrically connecting electronic components is formed on the electronic circuit board 3001 included in the functional unit 3000. The wiring pattern electrically connects the electronic components mounted on the electronic circuit board 3001. On the electronic circuit board 3001, an electronic component 3002 and a shield component 600 are mounted according to a wiring pattern. The electronic component 3002 and the shield component 600 are mounted on the electronic circuit board 3001 by soldering. On the electronic circuit board 3001, a land is formed at a mounting position where the electronic component 3002 and the shield component 600 are mounted.

FIG. 11 is a perspective view illustrating the shield component 600. As illustrated in FIG. 11, the shield component 600 has six side surface portions 601, 602, 603, 604, 605, and 606. The shield component 600 is mounted by soldering in a state where the lower end portions (edge portions) 601a, 602a, 603a, 604a, 605a, and 606a of the side surface portions 601 to 606 are in contact with the electronic circuit board 3001.

An upper end portion of the side surface portion 601~606 is bent toward the inside of the shield component 600. The shield component 600 is manufactured by cutting out one sheet metal with a mold and bending the sheet metal cut out so as to form the six side surface portions 601~606 illustrated in FIG. 11. Alternatively, the shield component 600 is manufactured by welding six sheet metal members so as to form the six side surface portions 601~606 illustrated in FIG. 11. By such a manufacturing method, the shield component 600 is formed such that the six side surface portions 601~606 surround an object to be shielded such as the electronic component 3002.

Note that the top surface of the shield component 600 illustrated in FIG. 11 is opened, but the present disclosure is not limited thereto, and as a modification, the shield component 600 may have a top plate that is not opened to the top surface. In the case of the shield component 600 in which the top surface is opened, there is an advantage that the heat radiation efficiency of the object to be shielded (for example, the electronic component 3002) can be improved, and in the case of the shield component in which the top plate is provided on the top surface, there is an advantage that the effect of suppressing the influence of noise can be improved.

The shield component 600 illustrated in FIG. 11 has a shape in which a quadrangle formed by the side surface portion 601 and the side surface portion 604 and a quadrangle formed by the side surface portion 603 and the side surface portion 606 which are shorter than the side surface portion 601 by a length corresponding to the side surface portion 605 are combined. Therefore, the center of gravity G of the shield component 600 (filled circle) is a position shifted from the center of gravity (dotted circle) assumed in the case of a quadrangle (rectangle) formed by the side surface portion 601 and the side surface portion 602. For example, regarding the side surface portion 601 of the shield component 600 and the side surface portion 603 facing the side surface portion 601, the center of gravity G is shifted to approach the side surface portion 601. That is, the distance from the center of gravity G to the side surface portion 603 is longer than the distance from the center of gravity G to the side surface portion 601. In addition, regarding the side surface portion 602 of the shield component 600 and the side surface portion 604 facing the side surface portion 602, the distance from the center of gravity G to the side surface portion 604 is longer than the distance from the center of gravity G to the side surface portion 602.

### Reflow soldering

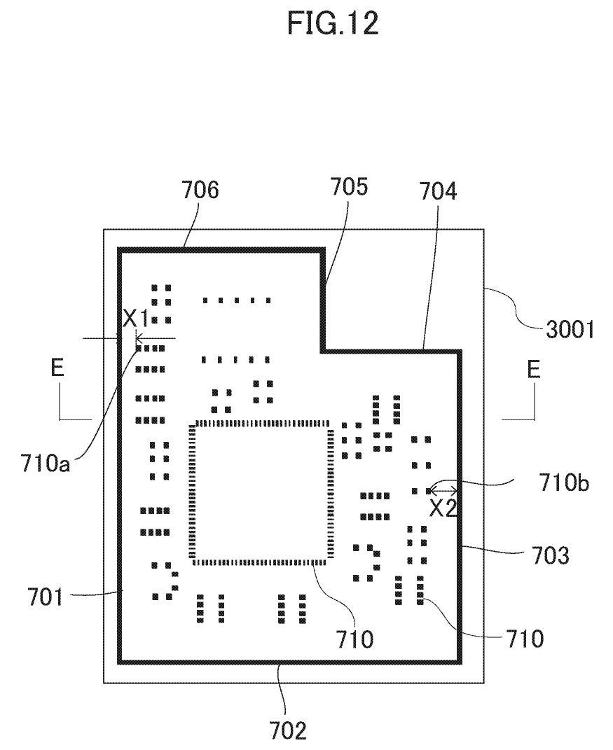

Here, reflow soldering for soldering the electronic component 3002 and the shield component 600 to the electronic circuit board 3001 will be described with reference to FIGS. 12 to 14 while referring to FIG. 11. In the present embodiment, the solder amount per unit area can be controlled by reflow soldering according to the position of the electronic circuit board 201 on which the electronic component 202 is mounted. First, as illustrated in FIG. 12, an electronic circuit board 3001 having a land for bonding the electronic component 3002 and the shield component 600 is prepared. That is, a method for manufacturing an electronic circuit board 3001 includes preparing a substrate having the lands 701 and 703. FIG. 12 is a top view illustrating an example of an electronic circuit board 3001 having lands 701, 702, 703, 704, 705, 706, and 710.

As illustrated in FIG. 12, the lands 701 to 706 are formed at a mounting position where the shield component 600 is mounted on the electronic circuit board 3001. More specifically, the lands 701, 702, 703, 704, 705, and 706 are formed at mounting positions for mounting the side surface portions 601, 602, 603, 604, 605, and 606, respectively. The land 710 is formed on the electronic circuit board 3001 at a mounting position where the electronic component 3002 is mounted. In FIG. 12, reference numeral "710" is not assigned to all the lands for redundancy. Lands 701 to 706 for bonding shield component 600 are disposed so as to surround land 710 for bonding electronic component 3002.

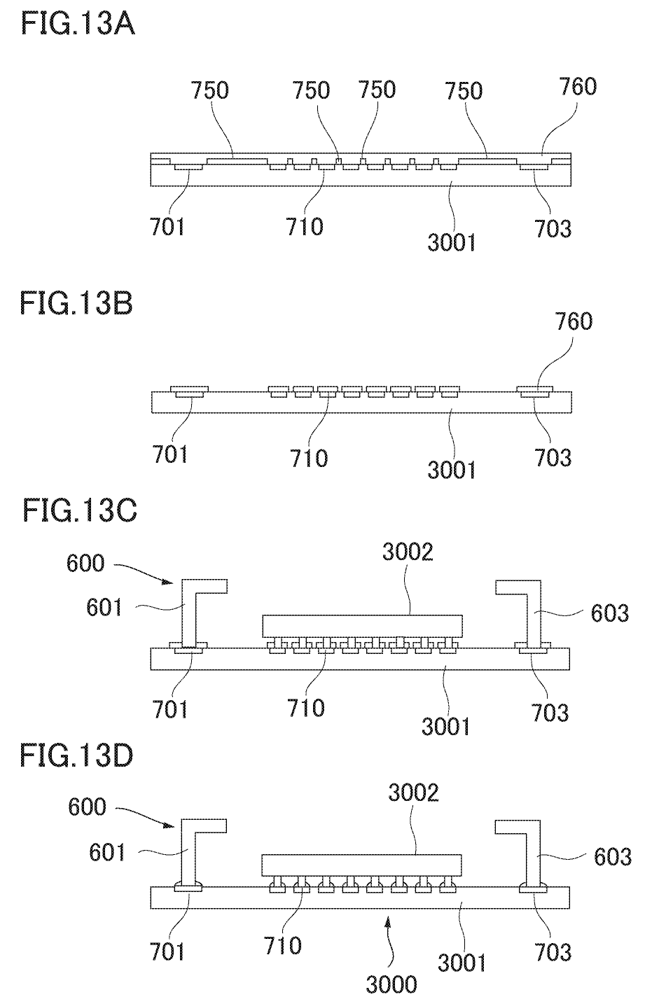

FIGS. 13A to 13D are diagrams for explaining reflow soldering. FIG. 13A is a view for explaining an arrangement step of overlapping the mask 750 on the electronic circuit board 3001 and arranging (for example, applying) the solder paste 760, and FIG. 13B is a view for explaining a removal step of removing the mask 750 from the electronic circuit board 3001 after the arrangement step. FIG. 13C is a view illustrating a mounting step of mounting the electronic component 3002 and the shield component 600 on the electronic circuit board 3001 from which the mask 750 has been removed, and FIG. 13D is a view illustrating a reflow step of reflowing the solder paste 760 remaining on the electronic circuit board 3001. For easy understanding of the description, FIGS. 13A to 13D illustrate cross sections taken along line E-E illustrated in FIG. 12.

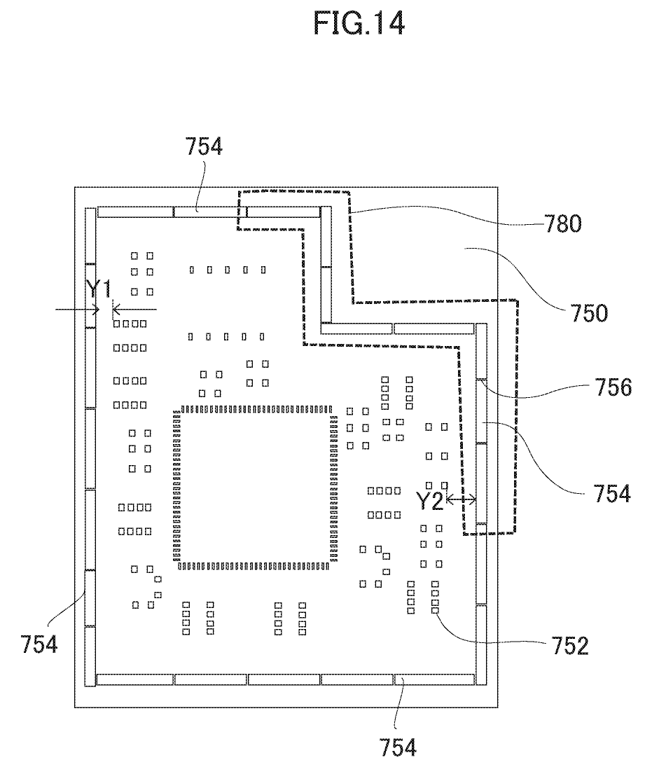

The method for manufacturing an electronic circuit board 3001 includes preparing the mask 750 having the openings 754a and 754b. In the process of FIG. 13A, the mask 750 is overlaid on the electronic circuit board 3001. The mask 750 is overlaid on the surface of the electronic circuit board 3001 on which the lands 701~706 and 710 are formed. That is, the method for manufacturing an electronic circuit board 3001 includes overlaying the mask 750 on the substrate such that the land 703 is exposed through the opening 754b and the land 701 is exposed through the opening 754a. A solder paste 760 as a solder material is applied from above the mask 750. For the solder paste 760, a paste-like conductive material having a constant viscosity is used. The mask 750 has an opening (see FIG. 14 described later). Since the electronic circuit board 3001 is exposed at the opening of the mask 750, the solder paste 760 is applied to the electronic circuit board 3001. That is, the method for manufacturing an electronic circuit board 3001 includes disposing a solder paste 760 on the mask 750 overlaying the substrate. On the other hand, since the electronic circuit board 3001 is not exposed at a portion other than the opening of the mask 750, the solder paste 760 is not applied to the electronic circuit board 3001. The openings of the mask 750 are formed at positions corresponding to the lands 701 to 706 and 710 (see FIG. 14 described later).

Here, the mask 750 used in the process of FIG. 13A will be described with reference to FIG. 14. FIG. 14 is a schematic diagram illustrating a shape of the mask 750. The mask 750 is formed of, for example, metal. Openings 752 and 754 are formed in the mask 750. In FIG. 14, not all the openings are denoted by reference numerals because of redundancy. The opening 752 corresponds to the land 710 of the electronic component 3002. The opening 754 corresponds to the lands 701 to 706 to which the shield component 600 is bonded. The lands 701 to 706 to which the shield component 600 is bonded are formed as one continuous region (see FIG. 12). On the other hand, the mask 750 is provided with a plurality of openings 754. This is to connect the portion inside the opening 754 of the mask 750 and the portion outside the opening 754. A coupling portion 756 is provided between the opening 754 and the opening 754.

In the process of FIG. 13B, the mask 750 described above is removed from the electronic circuit board 3001. That is, the method for manufacturing an electronic circuit board 3001 includes removing the mask 750 from the substrate after disposing the solder paste 760 on the mask 750overlaying the substrate. As the mask 750 is removed, the solder paste 760 applied to the opening portion of the mask 750 remains on the electronic circuit board 3001, and the solder paste 760 applied to portions other than the opening portion on the mask 750 is removed together with the mask 750. In the process of FIG. 13C, the electronic component 3002 and the shield component 600 are placed on the electronic circuit board 3001 from above the solder paste 760. That is, the method for manufacturing an electronic circuit board 3001 includes placing the electronic component 3002 and the shield component 600 on the substrate after removing the mask 750 from the substrate.

In the process of FIG. 13D, reflow of the solder paste 760 remaining on the electronic circuit board 3001 is performed. Specifically, in a state where the electronic component 3002 and the shield component 600 are placed on the electronic circuit board 3001, the solder paste 760 is heated and then cooled (reflow step). That is, the method for manufacturing an electronic circuit board 3001 includes reflowing the solder paste 760 remaining on the substrate after placing the electronic component 3002 and the shield component 600 on the substrate. In this way, the solder paste 760 is melted and then solidified again. When the solder paste 760 is melted, its shape changes due to surface tension. In addition, the molten solder paste 760 tends to gather in a highly hydrophilic portion. Typically, the metal exhibits high hydrophilicity to the solder paste 760. In the present embodiment, the lands 701 to 706 and 710, the terminals of the electronic component 3002, and the shield component 600 have high hydrophilicity. On the other hand, in order to control the shape of the solder paste 760, a water-repellent resist (not illustrated) is formed on the electronic circuit board 3001. As a result, the solder paste 760 is molded into a predetermined shape through the reflow step.

### Control of Solder Amount

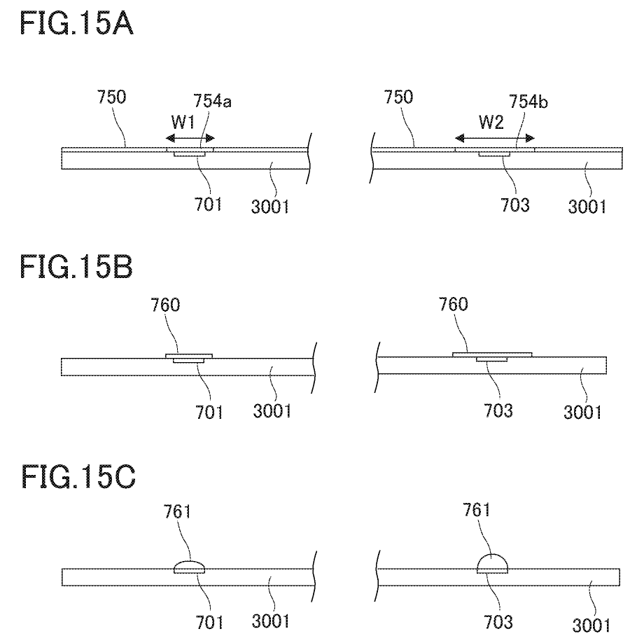

Next, a method for controlling the solder amount by reflow soldering of the present embodiment will be described with reference to FIGS. 15A to 15C. FIGS. 15A to 15C are enlarged views for explaining control of a solder amount by reflow soldering. For easy understanding of the description, FIGS. 15A to 15C illustrate cross sections taken along line E-E illustrated in FIG. 12.

The process of FIG. 15A illustrates an arrangement process corresponding to FIG. 13A. As described above, the mask 750 is provided with the openings 754a and 754b corresponding to the lands 701 and 703 to which the shield component 600 is bonded. Here, a mask 750 having an opening 754a having a relatively smaller width W1 at a position corresponding to the land 701 and having an opening 754b having a relatively larger width W2 at a position corresponding to the land 703 is used. That is, a relationship of "width W1<width W2" is established. The directions of the widths W1 and W2 are directions intersecting a direction (longitudinal direction) in which the edge portions 601a and 603a (see FIG. 11) of the shield component 600 extend.

FIG. 15B illustrates a removal step corresponding to FIG. 13B. When the mask 750 is removed from the electronic circuit board 3001, the area of the land 701 and the area of the land 702 are the same as each other, but the amount of the solder paste 760 left on the electronic circuit board 3001 is different from each other when comparing the left diagram and the right diagram of FIG. 15B. This is because the ratio of the size of opening 754a (second opening) of mask 750 to the area of land 701 (second land) is mutually different from the ratio of the size of opening 754b (first opening) of mask 750 to the area of land 703 (first land). The difference in the amount of the solder paste 760 remaining on the electronic circuit board 3001 is determined according to the difference between the width W1 and the width W2.

FIG. 15C illustrates a reflow step corresponding to FIG. 13D, and illustrates a state after the reflow step. Since the solder paste 760 is molded into a predetermined shape through the reflow step, in each of the land 701 and the land 702, the solder paste 760 is molded so as to fit in the lands 701 and 702. However, as described above, while the area of the land 701 and the area of the land 703 are the same, the amount of the solder paste 760 left on the electronic circuit board 3001 is different. That is, as a result of the reflow step, the amount of the solder paste 760 per unit area is different. As described above, the solder amount per unit area in each of the lands 701 and 702 can be controlled by changing the sizes of the openings 754a and 754b of the mask 750.

Thus, when the distance from the center of gravity G of the shield component 600 to the side surface portion 603 (first portion) is longer than the distance from the center of gravity G to the side surface portion 601 (second portion), the amount of the solder 761 disposed on the land 703 (first land) per unit area is greater than the amount of the solder 761 disposed on the land 701 (second land) per unit area.

In the present embodiment, as illustrated in FIG. 11, the center of gravity G of the shield component 600 is shifted from the center of gravity assumed in a case where the shape of the shield component is rectangular. In this case, when the shield component 600 is mounted on the electronic circuit board 3001 in the mounting process (see FIG. 13C), the shield component 600 may be disposed in an inclined manner. In the shield component 600, a portion in a direction in which the center of gravity G is shifted becomes relatively lower. In the shield component 600 illustrated in FIG. 11, the side surface portion 601 and the side surface portion 602 can be relatively lower with respect to the side surface portions 603 to 606. Therefore, a gap may be generated between the shield component 600 and the electronic circuit board 3001 in a part of the side surface portions 603 to 606.

Therefore, in the present embodiment, the mask 750 in which the width (W2) of the opening 754 in the region 780 surrounded by the dotted line illustrated in FIG. 14 is larger than the width (W1) of the opening 754 outside the region 780 is used (W1<W2). The region 780 is a portion corresponding to a part of the side surface portion 603, a part of the side surface portion 604, the side surface portion 605, and the side surface portion 606, and covers a range in which a gap is likely to be generated between the shield component 600 and the electronic circuit board 3001.

When the mask 750 is used, for example, as illustrated in FIG. 15C, a difference in the solder amount per unit area between the lands 701 and 703 in the region 780 and outside the region 780 appears as a difference in the height of the solder. That is, the solder 761 having a relatively higher height is formed in the land 703 (the portion where the shield component 600 is high) corresponding to the opening 754b in the region 780. Therefore, even if the shield component 600 is inclined, a gap is hardly generated between the shield component 600 and the electronic circuit board 3001. On the other hand, the solder 761 having a relatively lower height is formed in the land 701 (portion where the shield component 600 is lowered) corresponding to the opening 754a outside the region 780. Therefore, the possibility that an unintended electrical short circuit occurs due to the solder can be reduced. Therefore, the functional unit 3000 having the electronic circuit board 3001 on which the shield component 600 (or the electronic component 3002) that tends to tilt due to its shape is mounted can realize a desired function.

The solder amount per unit area will be additionally described. As described above, in the present embodiment, the width (W2) of the opening 754 in the region 780 is made relatively larger. Therefore, when the mask 750 is overlapped on the electronic circuit board 3001, the area of the land exposed from the opening 754 in the region 780 may be used as a denominator for calculating the amount per unit area. Then, the mass of the solder disposed on the land corresponding to the opening 754 in the region 780 can be a numerator for calculating the amount per unit area. Alternatively, in the present embodiment, the plurality of openings 754 is formed to have a relatively larger width (W2). Therefore, the area of the land exposed from one of these openings 754 may be used as a denominator for calculating the amount per unit area. In this case, the numerator is the mass of the solder in the corresponding region.

In the above description, the shield component 600 in which the center of gravity G is shifted due to the shape is taken as an example. However, the shift of the center of gravity of the mounted component is not limited to the shape. The center of gravity may change due to a difference in material, a density distribution, a thickness distribution, and the like. Therefore, the direction of shifting the center of gravity G is adjusted by these designs.

On the other hand, since differences in shape due to manufacturing variations occur randomly, it is difficult to predict or adjust in advance. For example, even at a position where the distance between the shield component and the electronic component is relatively shorter, shape variation such as generation of a gap may occur. If the solder amount is increased over the entire land in preparation for such a case, the shield component and the electronic component may be electrically and mechanically coupled by the solder, that is, a bridge due to the solder may occur.

Therefore, as in the shield component 600 of the present embodiment, by intentionally designing the direction in which the component is likely to tilt, it is possible to predict the region where the solder amount per unit area should be increased with high accuracy. As a result, it is easier for the functional unit 3000 to implement a desired function.

Furthermore, in a case where the inclination direction of the shield component 600 is intentionally designed, in other words, in a case where the position where the solder amount per unit area is to be increased and the position where the solder amount per unit area is to be decreased can be predicted, means for facilitating the function implementation of the functional unit 3000 can be taken. FIG. 12 illustrates distances X1 and X2, among the lands 701 to 706, two lands 701 and 703 to which the shield component 600 is bonded to the nearest, i.e., adjacent to, lands 710a and 710b of the lands 710 to which the electronic component 3002 is bonded. A distance from land 701 (second land) corresponding to side surface portion 601 (see FIG. 11) to the nearest land 710a (fourth land) is distance X1. A distance from land 703 (first land) corresponding to side surface portion 603 (see FIG. 11) to nearest land 710b (third land) is distance X2.

As illustrated in FIG. 12, the distance X2 is longer than the distance X1. Furthermore, the openings 754 of the mask 750 are formed in accordance with the relationship between the distance X1 and the distance X2 (see FIG. 14). In FIG. 14, the distance Y2 is longer than the distance Y1. Due to such a distance relationship, other lands are moved away from the land 703 where the solder amount per unit area is greater. Therefore, even if the solder amount becomes excessive and the solder may protrude from the land 703, it is possible to reduce the possibility of occurrence of bridging due to the solder. As a result, it is easier for the functional unit 3000 to implement a desired function.

According to the present disclosure, an electronic circuit board and a functional unit having components soldered to the electronic circuit board function appropriately.

### Other Embodiments

As in the above embodiment, the method for controlling the solder amount by reflow soldering of the present embodiment may be used for the purpose of compensating for the difference in the length of the terminal of the electronic component, compensating for the unevenness of the edge of the shield component, or controlling the component to be mounted to an intended posture.

In the embodiment described above, the method for controlling the solder amount by reflow soldering has been described. However, the method for controlling the solder amount per unit area is not limited to reflow soldering. For example, the solder amount can also be controlled by manual soldering using a soldering iron.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-024876, filed February 19, 2025 which is hereby incorporated by reference herein in its entirety.

What is claimed is:

1. An electronic circuit board for an image forming apparatus, the electronic circuit board comprising:
a substrate having a first land and a second land; and
at least one component mounted on the substrate by solder provided on the first land and solder provided on the second land,
wherein a per-unit-area solder amount of the solder provided on the first land differs from a per-unit-area solder amount of the solder provided on the second land.

2. The electronic circuit board according to claim 1, wherein
the at least one component includes a shield component including a first portion and a second portion,
the first portion is bonded to the substrate by the solder provided on the first land, and
the second portion is bonded to the substrate by the solder provided on the second land.

3. The electronic circuit board according to claim 2, wherein
an edge of the first portion facing the substrate forms a recess relative to an edge of the second portion facing the substrate, and
the per-unit-area solder amount of the solder provided on the first land is greater than the per-unit-area solder amount of the solder provided on the second land.

4. The electronic circuit board according to claim 2, wherein
a distance from the center of gravity of the shield component to the first portion is longer than a distance from the center of the gravity of the shield component to the second portion, and
the per-unit-area solder amount of the solder provided on the first land is greater than the per-unit-area solder amount of the solder provided on the second land.

5. The electronic circuit board according to claim 1, wherein
the at least one component includes a first component,
the first component includes a first portion bonded to the substrate by the solder provided on the first land, and a second portion bonded to the substrate by the solder provided on the second land,
a distance from the center of gravity of the first component to the first portion is longer than a distance from the center of the gravity of the first component to the second portion, and
the per-unit-area solder amount of the solder provided on the first land is greater than the per-unit-area solder amount of the solder provided on the second land.

6. The electronic circuit board according to claim 1, wherein the at least one component includes an electronic component.

7. The electronic circuit board according to claim 6, wherein
the electronic component includes a first terminal having a first length and a second terminal having a second length longer than the first length,
the first terminal is bonded to the substrate by the solder provided on the first land,
the second terminal is bonded to the substrate by the solder provided on the second land, and
the per-unit-area solder amount of the solder provided on the first land is greater than the per-unit-area solder amount of the solder provided on the second land.

8. The electronic circuit board according to claim 1, wherein
the per-unit-area solder amount of the solder provided on the first land is greater than the per-unit-area solder amount of the solder provided on the second land, and
a height of the solder provided on the first land is higher than a height of the solder provided on the second land.

9. The electronic circuit board according to claim 1, wherein
the substrate further includes a third land adjacent to the first land, and a fourth land adjacent to the second land,
a distance from the first land to the third land is longer than a distance from the second land to the fourth land, and
the per-unit-area solder amount of the solder provided on the first land is greater than the per-unit-area solder amount of the solder provided on the second land.

10. The electronic circuit board according to claim 1, wherein the solder provided on the first land and the solder provided on the second land are formed by reflowing solder material disposed through openings of mutually different sizes.

11. An image forming apparatus comprising:
a functional unit configured to perform at least a part of image forming functions,
wherein the functional unit includes the electronic circuit board according to claim 1.

12. A method for manufacturing an electronic circuit board, the method comprising:
preparing a substrate having a first land and a second land;
preparing a mask having a first opening and a second opening;
overlaying the mask on the substrate such that the first land is exposed through the first opening and the second land is exposed through the second opening;
disposing a solder material on the mask overlaying the substrate;
removing the mask from the substrate after disposing the solder material on the mask overlaying the substrate;
placing at least one component on the substrate after removing the mask from the substrate; and
reflowing the solder material remaining on the substrate after placing the at least one component on the substrate,
wherein a ratio of a size of the first opening to an area of the first land exposed through the first opening differs from a ratio of a size of the second opening to an area of the second land exposed through the second opening.
